(19) United States
(12) Patent Application Publication
(10) Pub. No.: US 2026/0065973 A1
(43) Pub. Date: Mar. 5, 2026

(54) MULTIPLEXING FOR MEMORY PACKAGES WITH BUFFER DIE AND MODULES WITH SAME

(71) Applicant: Micron Technology, Inc., Boise, ID (US)

(72) Inventors: Randall J. Rooney, Boise, ID (US); Matthew A. Prather, Boise, ID (US); Anthony D. Veches, Boise, ID (US); Navid Lashkarian, Pleasanton, CA (US); James J. O'Leary, Boise, ID (US); Sujeet Ayyapureddi, Boise, ID (US)

(73) Assignee: Micron Technology, Inc., Boise, ID (US)

(21) Appl. No.: 19/291,309

(22) Filed: Aug. 5, 2025

Related U.S. Application Data
(60) Provisional application No. 63/689,068, filed on Aug. 30, 2024.

(51) Int. Cl. G11C 11/4096; G11C 11/4076; G11C 11/4093

(52) U.S. Cl. CPC G11C 11/4096; G11C 11/4076; G11C 11/4093

(57) ABSTRACT

A memory package may include multiple memory die and a buffer die in some examples. The memory package may be included on a memory module. The memory module may include multiple memory packages. The buffer die may include components that reduce or eliminate a number of components on the memory module. In some embodiments, the buffer die may have components for performing error correction code operations, providing redundant memory portions, contention handling, multiplexing, interleaving, consolidating temperature and/or access information, self-testing, and/or self-training. In some examples, the memory package may include multilevel signaling, row buffers, memory built in self-testing, and/or modifications for processor-in-memory operations or accelerators therefor.

### CROSS REFERENCE TO RELATED APPLICATION(S)

This application claims the benefit under 35 U.S.C. § 119 of the earlier filing date of U.S. Provisional Application No. 63/689,068 filed Aug. 30, 2024, the entire contents of which is hereby incorporated by reference in its entirety for any purpose.

### BACKGROUND

This disclosure relates generally to semiconductor devices, and more specifically to semiconductor memory devices. In particular, the disclosure relates to memory, such as dynamic random access memory (DRAM). Information may be stored in memory cells, which may be organized into rows (word lines) and columns (bit lines) of an array. Various types of information may be stored in the array, such as data, error correction code (ECC) data, and metadata. The data may be information provided by an external device (e.g., controller, processor, host system). The ECC data may provide information that may be used to detect and/or correct errors in the data. The metadata may provide information about the data, ECC data, the memory device, and/or a device in communication with the memory device (e.g., a controller).

Semiconductor memory devices may store information in multiple memory cells. The information may be stored as a binary code, and each memory cell may store a single bit of information as either a logical high (e.g., a “1”) or a logical low (e.g., a “0”). The memory cells may be organized at the intersection of word lines (rows) and bit lines (columns) an array. The memory may further be organized into one or more memory banks. The banks may be organized into bank groups, where each bank group includes one or more banks. Each bank may include multiple of rows and columns. During operations, the memory device may receive a command and an address which specifies one or more rows and one or more columns and then execute the command on the memory cells at the intersection of the specified rows and columns (and/or along an entire row/column). The address may further specify the bank group and/or bank for execution of the command. In some applications, rows may be specified by 17-bit row addresses and columns may be specified by 12-bit column addresses. However, the number of bits used for the addresses may vary depending on the size and/or organization of the memory.

The columns may generally be organized into column planes, each of which includes a number of sets of individual columns all activated by a column select signal (CS) (e.g., column selects). Each bank may include some number X column planes. A column plane may receive some number N of column select (CS) signals, each of which may activate some number M of individual bit lines. As used herein, a column select set or CS set may generally refer to a set of bit lines which are activated by a given value of the CS signal within a column plane. The column select signal may be represented by (all or a portion of) a column address (CA). Responsive to a column select signal, data may be provided from corresponding locations from the column planes. The data from the column planes associated with the column select signal may be referred to as a cache line.

In many applications, multiple memory devices are used by a device and/or computing system. The memory devices may be packaged together in a memory module. For example, single in-line memory modules (SIMMs), dual in-line memory modules (DIMMS), small outline DIMMs (SODIMMs), and rambus in-line memory modules (RIMM) may include multiple memory devices.

FIG. 1A is a block diagram of at least a portion of a computing system. The computing system 10 includes a memory module 12 and a controller 16 in communication with the memory module 12. The memory module 12 may include module logic and buffers 18 and one or more memory devices 14.

The controller 16 may provide commands, addresses (CA), clock signals (CLK), and/or to one or more of the memory devices 14 and receive data from one or more of the memory devices 14. As shown, some or all of the signals transmitted between the controller 16 and memory devices 14 must pass through the module logic and buffers 18. The module logic and buffers 18 may facilitate coordination between the memory devices 14 (e.g., distributing clock signals). However, module logic and buffers 18 may also lead to “middleman” inefficiencies. Further, the module logic and buffers 18 are typically manufactured by an entity different from the entities that manufactured the memory devices 14 and controller 16. This may lead to quality control issues and/or unforeseen compatibility issues.

### BRIEF DESCRIPTION OF THE DRAWINGS

FIG. 1A is a block diagram of at least a portion of a computing system.

FIG. 1B is a block diagram of at least a portion of a computing system according to some embodiments of the present disclosure.

FIG. 2A is a diagram showing a multi-die device according to an embodiment of the disclosure.

FIG. 2B is a diagram showing a multi-die device according to an embodiment of the disclosure.

FIG. 2C is a block diagram of a semiconductor device according to some embodiments of the present disclosure.

FIG. 3 is a functional block diagram of a memory module according to at least one embodiment of the disclosure.

FIG. 4 is a flow chart illustrating a method according to at least one embodiment of the present disclosure.

FIG. 5 is a flow chart illustrating a method according to at least one embodiment of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

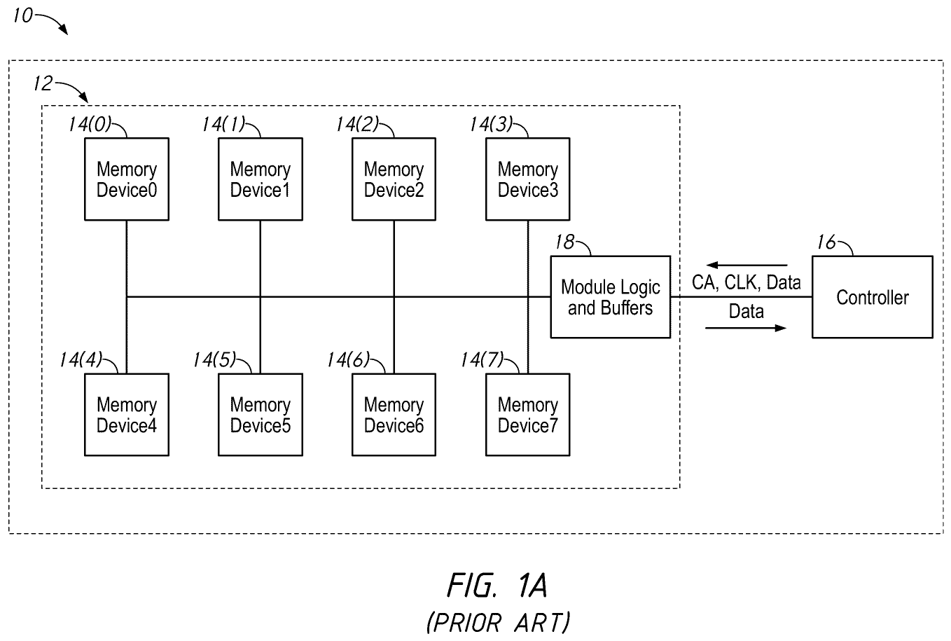

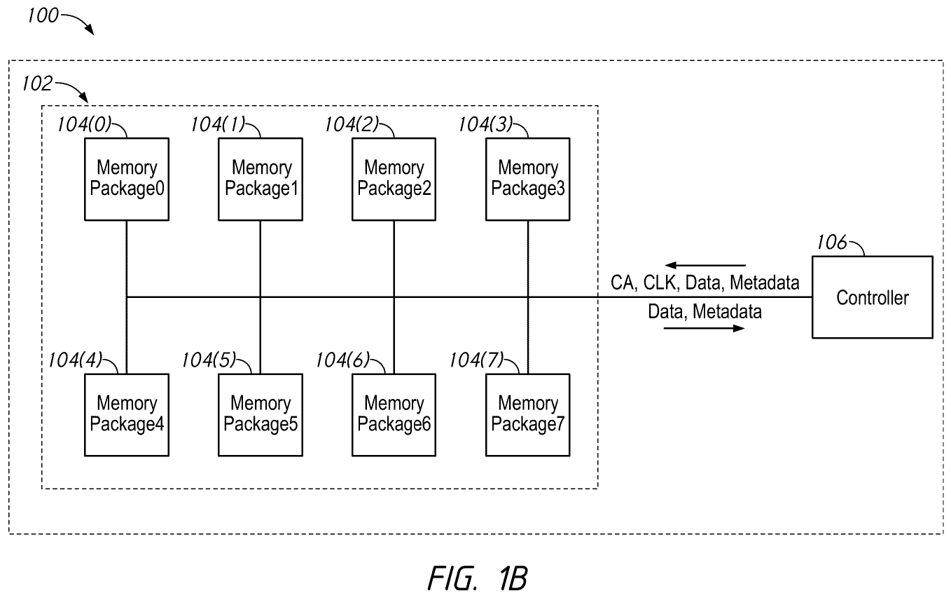

FIG. 1B is a block diagram of at least a portion of a computing system according to some embodiments of the present disclosure. The computing system 100 includes a memory module 102 and a controller 106 in communication with the memory module 102. In some embodiments, the controller 106 may be included in a processor (not shown) or in communication with the processor. The memory module 102 may include one or more memory packages 104. According to embodiments of the present disclosure, each memory package 104 may one or more memory devices and a buffer die. The memory devices may be stacked on the buffer die in some examples. In the example shown in FIG. 1, there are eight memory packages 104(0-7). However, in other embodiments, there may be more or fewer memory packages (e.g., 1 device, 2, devices, 4 devices, 16 devices). In some embodiments, additional memory packages 104 may be included to provide for redundancy. In some embodiments, memory module 102 may be a dual in-line memory module (DIMM). In some embodiments, what is shown in FIG. 1 may represent only half of the DIMM (e.g., one of the two channels). In other words, memory module 102 may include sixteen memory packages 104.

The controller 106 may provide signals such as commands, addresses, clock signals and/or data (e.g., data, metadata, or both) to one or more of the memory packages104 and receive signals such as data from one or more of the memory packages 104. According to embodiments of the present disclosure, the controller 106 may provide and receive signals from the memory die via the buffer die. In some embodiments, memory package 104 may be x16 or x32 memory devices. That is, either 16 or 32 DO terminals (e.g., pins) may be active. In some embodiments, the memory package 104 may support both x16 and x32 operation. In some embodiments, whether the memory package 104 operate in x4 or x8 mode may be based, at least in part, on values stored in mode registers (not shown in FIG. 1) of the memory packages 104. In some embodiments, the memory packages 104 may be x4, x8, or x64 memory packages.

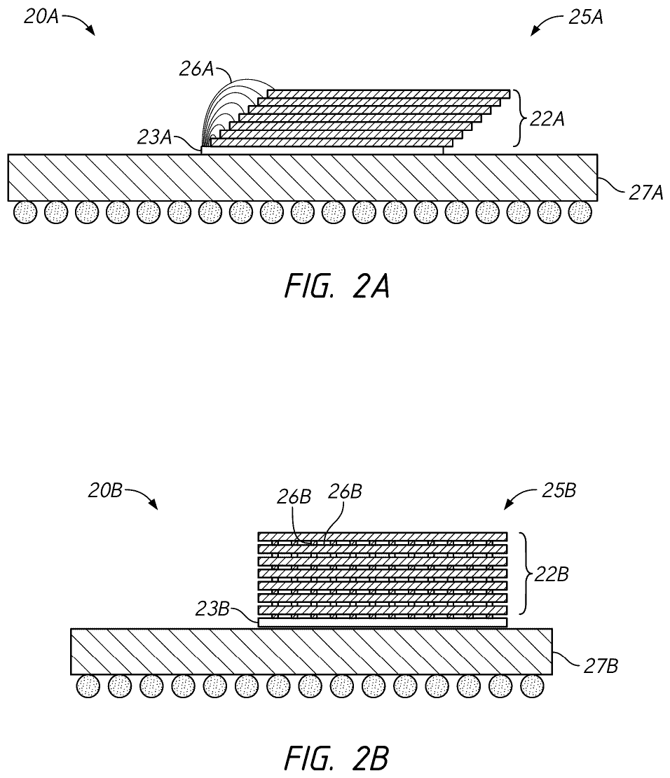

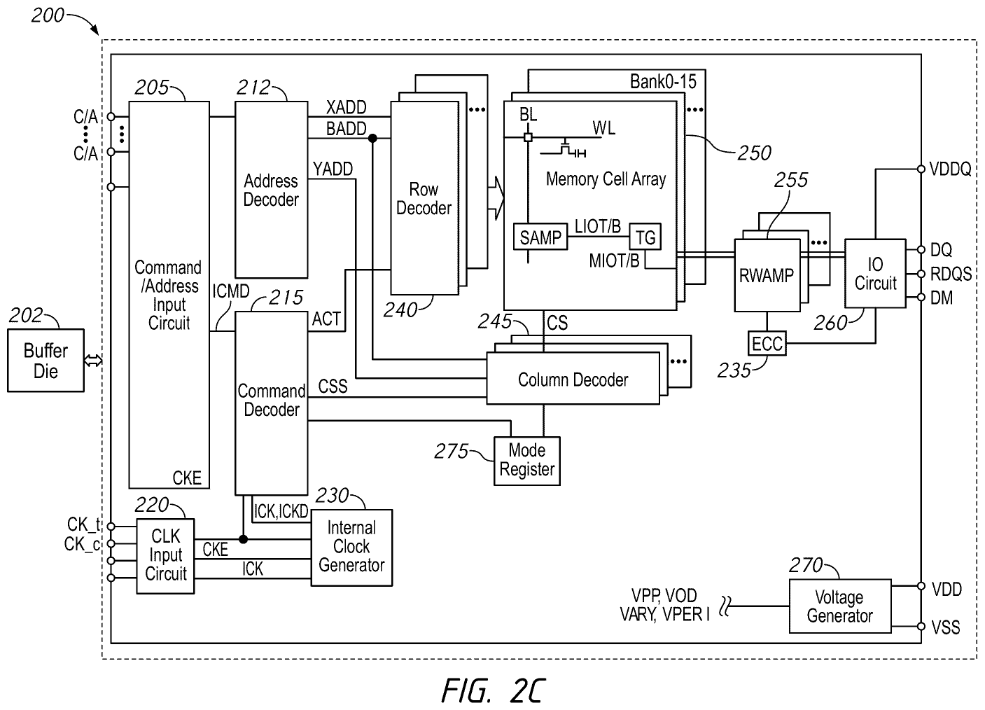

FIG. 2A is a diagram showing a multi-die device according to an embodiment of the disclosure. The multi-die device 20A may include a stack 25A of memory devices 22A (e.g., memory die) and a buffer die 23A. Embodiments of the disclosure are not limited to the particular number of memory devices 22A included in the stack 25A shown in FIG. 2A. For example, the stack 25A may include 1-16 memory devices 22A. Further, while one buffer die 23A is shown in FIG. 2A, in some embodiments, there may be two buffer die 23A per stack 25A. In some embodiments of the disclosure, the stack 25A may be included in one or more of memory packages 104.

The memory devices 22A and buffer die 23A may be stacked in a staggered manner, providing a “shingle-stack” configuration for the stack 25A as shown in FIG. 2A. However, the memory devices 22A and buffer die 23A may be stacked in other configuration such as a staggered configuration. The memory devices 22A and/or buffer die 23A may be attached to one another. In some embodiments of the disclosure, the semiconductor devices 22A are attached to one another by an adhesive epoxy.

The memory devices 22A and/or buffer die 23A may include a pad formation area, a peripheral circuit area, and memory cell array areas (not shown in FIG. 2A) that include memory cells, circuits, and signal lines, for example, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 22A and/or buffer die 23A.

The pad formation area may include a plurality of bond pads disposed along the edge of the memory devices 22A and/or buffer die 23A. The plurality of bond pads may be coupled to the terminals of the semiconductor device and represent external terminals of the memory devices 22A and/or buffer die 23A. For example, the plurality of bond pads may include data terminals, command and address terminals, clock terminals, and/or power supply terminals.

Circuits included in the memory cell array area and/or circuits of the peripheral circuit area may be coupled to one or more bond pads included in the pad formation area. Various circuits of the memory devices 22A and/or buffer die 23A may be coupled to the terminals. Conductive structures may be used to couple the terminals to one or more of the bond pads. As a result, the circuits coupled to the terminals are also coupled to the bond pads. The conductive structures may extend from locations of the terminals included in the memory cell array area and/or the peripheral circuit area to the pad formation area.

The memory devices 22A may be offset from one another to allow edge regions of the memory devices 22A to be exposed. The exposed edge regions may include the bond pads to which conductors 26A may be coupled. In some embodiments of the disclosure, the bond pads of the edge regions may be conductive pads. The bond pads may be coupled to terminals of the respective memory device 22A. In some embodiments of the disclosure, the conductors 26A are bond wires. While the conductors 26A in FIG. 2A are shown coupling all of the memory devices 22A to the buffer die 23A, the conductors 26A may be coupled in other configurations. For example, the conductors 26A may couple adjacent memory devices 22A to one another, and the lowest memory device 22A may be coupled to the buffer die 23A by the conductors 26A in a “daisy chain” configuration.

The stack 25A may be attached to a substrate 27A. The stack 25A may be attached to the substrate 27A by an adhesive epoxy in some embodiments of the disclosure. The substrate 27A may include conductive signal lines to route signals along the substrate, for example, to and from the memory devices 22A and/or buffer die 23A. Other circuits may also be attached to the substrate 27A and coupled to the conductive signals lines as well. As a result, the circuits attached to the substrate 27A may be coupled, for example, to the memory devices 22A and/or buffer die 23A through the conductive signal lines of the substrate 27A and conductors coupled to the conductive signal lines and the bond pads of the memory devices 22A and/or buffer die 23A. In some embodiments, the substrate 27A may be included in memory module 102.

FIG. 2B is a diagram showing a multi-die device according to an embodiment of the disclosure. The multi-die device 20B may include a stack 25B of memory devices 22B and a buffer die 23B. Embodiments of the disclosure are not limited to the particular number of memory devices 22B included in the stack 25B shown in FIG. 2B. For example, the stack 25B may include 1-16 memory devices 22B. Further, while one buffer die 23B is shown in FIG. 2B, in some embodiments, there may be two buffer die 23B per stack 25B. In some embodiments of the disclosure, the stack 25B may be included in one or more of the memory packages 104.

The memory devices 22B and/or buffer die 23B may include a pad formation area, a peripheral circuit area, and memory cell array areas (not shown in FIG. 2B) that include memory cells, circuits, and signal lines, for example, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 22B and/or buffer die 23B.

The memory devices 22B and buffer die 23B may be stacked in an aligned manner, such that the edges of the memory devices 22B are substantially aligned. When the buffer die 23B is a similar dimension to the memory devices 22B, the buffer die 23B may be substantially aligned with the memory devices 22B as well as shown in FIG. 2B. However, the memory devices 22B and buffer die 23B may be stacked in other configuration such as a staggered configuration.

In contrast to stack 25A, the memory devices 22B and/or buffer die 23B are electrically coupled to one another by through silicon vias (TSVs) 26B rather than being coupled by conductors 26A. In some embodiments, instead of or in addition to pad formation areas, the memory devices 22B and/or buffer die 23B may include TSV formation areas. The memory devices 22B and/or buffer die 23B may be physically attached to one another by additional mechanisms (e.g., not just the TSVs). In some embodiments of the disclosure, the semiconductor devices 22B are attached to one another by an adhesive epoxy.

The stack 25B may be attached to a substrate 27B. The stack 25B may be attached to the substrate 27B by an adhesive epoxy in some embodiments of the disclosure. The substrate 27B may include conductive signal lines to route signals along the substrate, for example, to and from the memory devices 22B and/or buffer die 23B. Other circuits may also be attached to the substrate 27B and coupled to the conductive signals lines as well. As a result, the circuits attached to the substrate 27B may be coupled, for example, to the memory devices 22B and/or buffer die 23B through the conductive signal lines of the substrate 27B and conductors coupled to the conductive signal lines and the bond pads of the memory devices 22B and/or buffer die 23B. In some embodiments, the substrate 27B may be included in memory module 102.

In some embodiments, the buffer die 23A, 23B is a memory device substantially similar to memory devices 22A, 22B. In some embodiments, memory devices 22A, 22B may have certain logic circuits disabled and/or bypassed, and the buffer die 23A, 23B has such logic circuits enabled and acts as a “target” or “master” die. In some embodiments, the buffer die 23A, 23B is a different device with different components than the memory devices 22A, 22B. According to embodiments of the present disclosure, the buffer die 23A, 23B may include buffers for buffering and/or arranging data received from the memory devices 22A, 22B prior to providing to a controller and arranging data received from the controller prior to providing to the memory devices 22A, 22B.

As described in more detail herein, the buffer die 23A, 23B may include components for multiplexing data between memory devices 22A, 22B. Additionally, in some embodiments, memory modules including multi-die stack memory packages may include components for buffering, multiplexing and/or interleaving data between memory packages. In some applications, this may reduce or eliminate the need for additional components on the memory modules, which may reduce compatibility issues. In some applications, the multiplexing components of the memory package may be included in addition to the multiplexing components of the memory module. This may increase the multiplexing capabilities of the memory module.

FIG. 2C is a block diagram of a memory device according to some embodiments of the present disclosure. The apparatus may be a semiconductor device. In some embodiments, the memory device 200 may include, without limitation, a dynamic random access (DRAM) device integrated into a single semiconductor chip. In some examples, the DRAM may be a double data rate (DDR) memory device. In some embodiments, it may be a DDR5 or DDR6 memory device. In some embodiments, one or all of the memory devices 22A, 22B of FIGS. 2A and 2B may include memory device 200.

The memory device 200 includes a memory array 250. The memory array 250 includes a plurality of banks BANK0-15, each bank including a plurality of word lines WL, a plurality of bit lines BL, and a plurality of memory cells MC arranged at intersections of the plurality of word lines WL and the plurality of bit lines BL. Although sixteen banks are shown in FIG. 2, memory array 250 may include any number of banks. The selection of the word line WL is performed by a row decoder 240 and the selection of the bit line BL is performed by a column decoder 245. Sense amplifiers (SAMP) are located for their corresponding bit lines BL and connected to at least one respective local I/O line pair (LIOT/B), which is in turn coupled to at least respective one main I/O line pair (MIOT/B), via transfer gates (TG), which function as switches. The TG may be coupled to one or more read/write amplifiers (RWAMP) 255, which may be coupled to an error correction code (ECC) circuit 235. The ECC circuit 235 may be coupled to an IO circuit 260, which may be coupled to one or more external terminals of semiconductor device 200. Read data from the bit line BL is amplified by the sense amplifier SAMP, and transferred to read/write amplifiers 255 over complementary local data lines (LIOT/B), transfer gate (TG), and complementary main data lines (MIOT/B) to the ECC circuit 235. Conversely, write data outputted from the ECC circuit 235 is transferred to the sense amplifier SAMP over the complementary main data lines MIOT/B, the transfer gate TG, and the complementary local data lines LIOT/B, and written in the memory cell MC coupled to the bit line BL.

The memory device 200 may employ a plurality of external terminals that include command and address terminals coupled to a command/address (C/A) bus to receive command and address signals, clock terminals to receive clock signals CK_t and CK_c, data terminals DO, RDQS, and power supply terminals VDD, VSS, VDDQ, and VSSQ.

The C/A terminals may be supplied with an address and a bank address signal from outside, for example, from a buffer die 202. Buffer die 202 may be buffer die 23A and/or buffer die 23B in some embodiments. The address signal and the bank address signal supplied to the address terminals are transferred, via a command/address input circuit 205, to an address decoder 212. The address decoder 212 receives the address signals and supplies a decoded row address signal XADD to the row decoder 240, and a decoded column address signal YADD to the column decoder 245. The address decoder 212 also receives the bank address signal BADD and supplies the bank address signal to the row decoder 240 and the column decoder 245.

The C/A terminals may further be supplied with command signals from, for example, buffer die 202. In some embodiments, buffer die 202 may receive commands and addresses from a controller, such as controller 106. The command signals may be provided as internal command signals ICMD to a command decoder 215 via the command/address input circuit 205. The command decoder 215 includes circuits to decode the internal command signals ICMD to generate various internal signals and commands for performing operations, for example, a row activation signal (ACT) to select a word line. Another example may be providing internal signals to enable circuits for performing operations, such as control signals to enable signal input buffers that receive clock signals.

Each bank BANK0-15 may be organized into multiple physical column planes (CP). Each column plane may be associated with multiple column selects (e.g., CS0-63, CS0-59, CS0-55). In some embodiments, different column planes may be used to store different types of information. For example, some column planes may store data and another plane stores ECC data. Optionally, a further plane may store global column redundancy (GCR) data. Optionally, the array 250 can store metadata in one or more column planes. In some embodiments, a column plane may store more than one type of information (e.g., data and metadata, metadata and ECC data)

The C/A terminals may receive an access command which is a read command. When a read command is received, and a bank address, a row address and a column address are timely supplied with the read command, a codeword including read data, metadata, and read ECC data (e.g., parity bits) is read from memory cells in the memory array 250 corresponding to the row address and column address. The read command is received by the command decoder 215, which provides internal commands so that read data from the memory array 250 is provided to the ECC circuit 235. The ECC circuit 235 may use the parity bits in the codeword to determine if the codeword includes any errors, and if any errors are detected, may correct them to generate a corrected codeword (e.g., by changing a state of the identified bit(s) which are in error). The corrected codeword (without the parity bits) is output from the data terminals DO via the input/output circuit 260.

The C/A terminals may receive an access command which is a write command. When the write command is received, and a bank address, a row address, and a column address are timely supplied as part of the write operation, and write data is supplied through the DO terminals to the ECC circuit 235. The write data (which may include write data and metadata) supplied to the data terminals DO is written to a memory cells in the memory array 250 corresponding to the row address and column address. The write command is received by the command decoder 215, which provides internal commands so that the write data is received by data receivers in the input/output circuit 260. The write data is supplied via the input/output circuit 260 to the ECC circuit 235. The ECC circuit 235may generate ECC data (e.g., a number of parity bits) based on the write data, and the write data and the parity bits may be provided as a codeword to the memory array 250 to be written into the memory cells MC.

The command decoder 215 may access mode register 275 that is programmed with information for setting various modes and features of operation for the semiconductor device 200. For example, the mode register 275 may provide parameters that allow the semiconductor device 200 to operate at different frequencies, provide different burst lengths, allow banks BANK0-15 to be organized into different groups, operate in x8 or x16 mode, and/or other different operating conditions. In some embodiments, mode register 275 may include multiple registers.

The information in the mode register 275 may be programmed by providing the memory device 200 a mode register write command, which causes the memory device 200 to perform a mode register write operation. In some embodiments, data to be written to the mode register 275 is provided via the C/A terminals and/or the DO terminals. The command decoder 215 accesses the mode register 275, and based on the programmed information along with the internal command signals provides the internal signals to control the circuits of the semiconductor device 200 accordingly. Information programmed in the mode register 275 may be externally provided by the memory device 200 using a mode register read command, which causes the memory device 200 to access the mode register 275 and provide the programmed information (e.g., to the buffer die 202). In some embodiments, the information may be provided via the C/A terminals and/or the DO terminals.

Turning to the explanation of the external terminals included in the memory device 200, the clock terminals and data clock terminals are supplied with external clock signals and complementary external clock signals. The external clock signals CK_t, CK_c may be supplied to a clock input circuit 220. When enabled, input buffers included in the clock input circuit 220 pass the external clock signals. For example, an input buffer passes the CK_t and CK_c signals when enabled by a CKE signal from the command decoder 215. The clock input circuit 220 may use the external clock signals passed by the enabled input buffers to generate internal clock signal ICK. The internal clock signal ICK are supplied to internal clock circuit 230 for providing one or more clock signals to the various components of memory device 200.

The internal clock circuits 230 includes circuits that provide various phase and frequency controlled internal clock signals based on the received internal clock signals. For example, the internal clock circuits 230 may include a clock path (not shown in FIG. 2) that receives the ICK clock signal and provides internal clock signals ICK and ICKD to the command decoder 215. Optionally, the input/output circuit 260 may include clock circuits and driver circuits for generating and providing the RDQS signal to a controller.

The power supply terminals are supplied with power supply potentials VDD and VSS. These power supply potentials VDD and VSS are supplied to an internal voltage generator circuit 270. The internal voltage generator circuit 270 generates various internal potentials VPP, VOD, VARY, VPERI. The internal potential VPP is mainly used in the row decoder 240, the internal potentials VOD and VARY are mainly used in the sense amplifiers included in the memory array 250, and the internal potential VPERI is used in many other circuit blocks.

The power supply terminal is also supplied with power supply potential VDDQ. The power supply potentials VDDQ is supplied to the input/output circuit 260 together with the power supply potential VSS. The power supply potential VDDQ may be the same potential as the power supply potential VDD in an embodiment of the disclosure. The power supply potential VDDQ may be a different potential from the power supply potential VDD in another embodiment of the disclosure. However, the dedicated power supply potential VDDQ is used for the input/output circuit 260 so that power supply noise generated by the input/output circuit 260 does not propagate to the other circuit blocks.

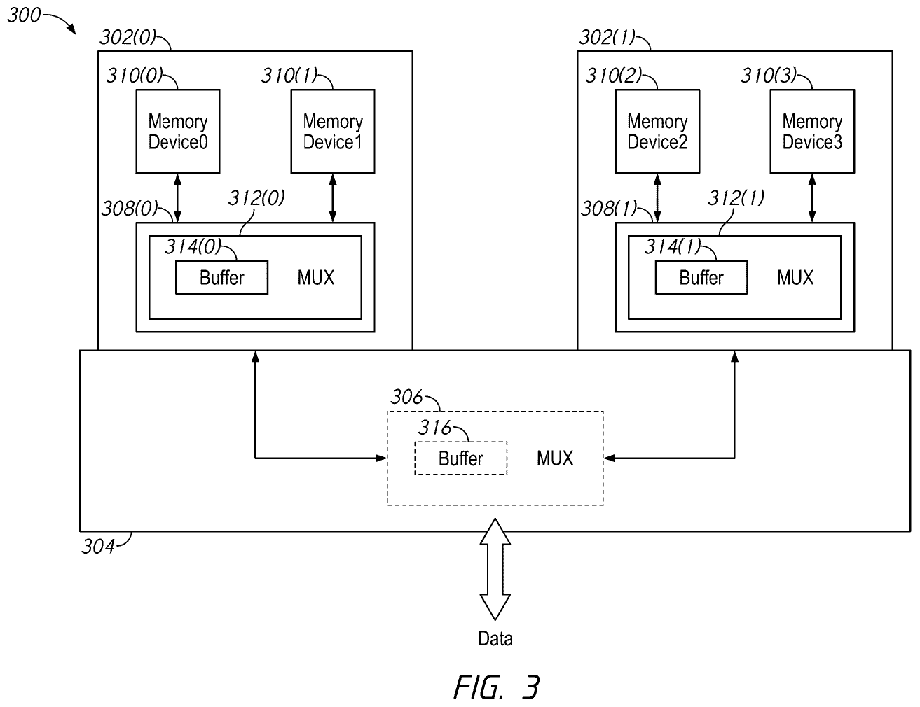

FIG. 3 is a functional block diagram of a memory module according to at least one embodiment of the disclosure. Memory module 300 may be included in memory module 102 in some embodiments. Memory module 300 may include memory packages 302, board 304, and optionally, multiplexer (MUX) 306. Memory module 300 is shown including two memory packages 302(0-1). However, memory module 300 may include any number of memory packages 302 in other examples (e.g., 4, 8, 16 memory packages). Memory packages 302 may include a buffer die 308 and memory devices 310. While two memory devices 310 are included in each memory package 302 as shown in FIG. 3, any number of memory devices 310 may be included. In some embodiments, the memory devices 310 may include memory device 200 shown in FIG. 2C. In some embodiments, buffer die 308 may include buffer die 202, buffer die 23A, and/or buffer die 23B. In some embodiments, the memory package 302 may be used to implement one or more of memory packages 104 shown in FIG. 1B. As noted, FIG. 3 is a functional block diagram, and the arrangement of the components is to illustrate the passing of information between components and is not meant to reflect the physical arrangement of the components.

Existing multiplexed rank dual inline memory modules (MRDIMM) provide higher bandwidth and lower latency by multiplexing data between ranks of memory devices. For example, 64 bytes may be provided from one rank of memory and 64 bytes may be provided from another rank of memory, and the full 128 bytes are provided from a multiplexer and/or buffer on the module. However, the multiplexer and other components on the MRDIMM may be from a different manufacturer than the memory devices, which may increase the risk of operability issues.

According to embodiments of the present disclosure, the buffer die 308 of a memory package 302 may include MUX 312. The MUX 312 may include one or more buffers 314. The buffers 314 may temporarily store data during read and write operations. In some embodiments, the memory devices 310 may be organized into ranks. In package 302(0), memory device 310(0) may be a first rank and memory device 310(1) may be a second rank. Of course, in other embodiments, such as when memory package 302(0) includes more than two memory devices 310, more than one memory device may be included in a rank.

In some embodiments, during a read operation, buffer die 308(0) may receive data from memory device 310(0) and 310(1) at MUX 312(0). The data from memory devices 310(0-1) may be arranged in and then output from the buffer 314(0) in some embodiments. The MUX 312(0) and/or other components of the buffer die 308(0) (e.g., additional buffers, I/O circuits) may output the data from memory devices 310(0-1) from the memory package 302(0). In some embodiments, the data from memory package 302(0) may be provided to a controller (not shown in FIG. 3). Memory package 302(1) may operate in a substantially same manner as memory package 302(0).

During a write operation, the buffer die 308(0) may receive data associated with a write command (e.g., from a controller), and the data may be provided to MUX 312(0). Some data associated with the write command may be provided to memory device 310(0) and other data associated with the write command may be provided to memory device 310(1) by the MUX 312(0). In some embodiments, the data may be temporarily stored in the buffer 314(0) before being provided to the memory devices 310.

The MUX 312 and/or other components for providing data to and from the memory package 302 may have a larger bandwidth than the individual memory devices 310. For example, each memory device 310 may be x16 devices, and MUX 312 and/or the memory package 302 may be x32. These embodiments may allow increase bandwidth. For example, a controller may “see” a x32 memory device even though each memory device 310 is x16.

In some embodiments, the MUX 312 may interleave data to and from memory devices 310. In some embodiments, the MUX 312 may interleave data to and from memory devices based, at least in part, on rank. In some embodiments, MUX 312 may provide data to or from one rank followed by data to or from the other rank. MUX 312(0) may interleave data to or from memory device 310(0) and memory device 310(1).

For example, during a read operation, MUX 312(0) may receive data from memory device 310(0) and memory device 310(1), and alternate providing data from memory device 310(0) and providing data from memory device 310(1). In some embodiments, MUX 312(0) may receive data from memory device 310(0) responsive to a first read command and receive data from memory device 310(1) responsive to a second read command. MUX 312(0) may transmit data from memory device 310(0) followed by data from memory device 310(1). In some embodiments, data from memory device 310(0) and/or memory device 310(1) may be temporarily stored in buffer 314(0). In some embodiments, the MUX 312(0) may and/or other components of the buffer die 308(0) may output the data from memory devices 310(0-1) from the memory package 302(0). In some embodiments, the data from memory package 302(0) may be provided to a controller (not shown in FIG. 3). Memory package 302(1) may operate in a substantially same manner at memory package 302(0).

During a write operation, the buffer die 308(0) may receive data associated with a write command (e.g., from a controller), and the data may be provided to MUX 312(0). The MUX 312(0) may provide the data associated with the write command to memory device 310(0). A second write command and associated data may be received, and MUX 312(0) may provide the data associated with the second write command to memory device 310(1). In some embodiments, buffer 314(0) may temporarily store the data associated with the first or second write command.

Interleaving data from the memory devices 310 may allow a reduction in latency while maintaining a same 10 width of the memory package 302. By interleaving data from the memory devices 310, data from one memory device 310 can be provided from the memory package 302 while additional data from another memory device 310 is being retrieved. In some applications, this embodiment may be desirable when space is limited, and additional data pads cannot be added to increase the IO width. In other applications, interleaving data may allow for memory package 302(0) to accommodate longer burst lengths. For example, memory device 310(0) may provide the first 16 bits of a 32-bit burst, and memory device 310(1) may provide the second 16 bits of the 32-bit burst.

In some embodiments, the data from memory packages 302 may be provided to a controller via conductive traces and data pads on the memory module 300 (not shown). Optionally, in other embodiments, the memory module 300 includes MUX 306, which may include buffer 316, to provide additional multiplexing and interleaving. In some embodiments, the memory packages 302 may be organized into ranks. For example, memory package 302(0) may be a first rank and memory package 302(1) may be a second rank.

The MUX 306 may receive data from both memory packages 302, and the data may for output to a controller during read operations. The MUX 306 may transmit data to both memory packages 302 for storage during write operations. This may allow the memory module 300 to have a larger bandwidth than the individual memory packages 302. The principle may be similar to the increased bandwidth of the individual memory packages 302. For example, each memory device 310 may be x8. Utilizing the MUX 312 and/or buffer 314, the memory packages 302 may be x16. Utilizing the MUX 306 and/or buffer 316, the memory module 300 may be x32. In some embodiments, the MUX 306 may interleave data to and from memory packages 302(0) and 302(1). This may reduce latency of the memory module 300 in some embodiments and/or allow for longer burst lengths.

The multiplexing and buffering at the memory package 302 level may allow for higher bandwidths and/or lower latency. In some embodiments, the memory devices 310 may operate at a lower speed (e.g., ½) because accesses occur at a lower rate. The multiplexing and buffering at the memory module 300 level may allow for even higher bandwidths and/or lower latencies. In some embodiments, the memory devices 310 may operate at even lower speeds (e.g., %) because accesses occur at a lower rate. However, external devices, such as a controller, “see” the same and/or higher access rates. In some embodiments, the memory arrays of the memory devices 310 may be organized into fewer banks because the lower access rates reduce bank availability issues.

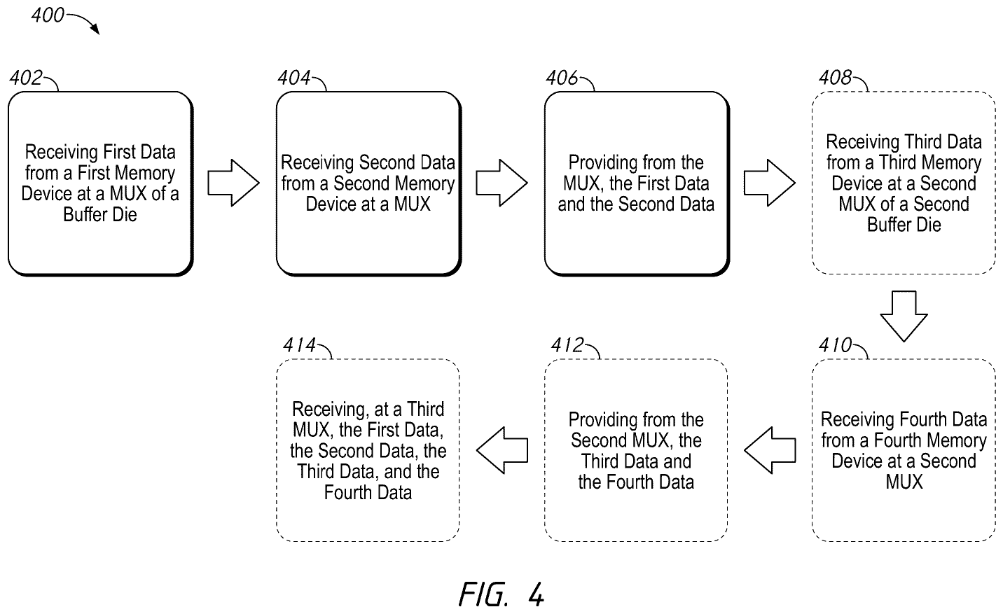

FIG. 4 is a flow chart illustrating a method according to at least one embodiment of the present disclosure. The method shown in flowchart 400 may be performed in whole or in part by any or all of the memory packages disclosed herein, such as memory package 302, in some embodiments. The method shown in flowchart 400 may be performed in whole or in part by a memory module, such as memory module 300 and/or memory module 102 in some embodiments.

At block 402, “receiving first data from a first memory device at a MUX of a buffer die” may be performed. At block 404, “receiving second data from a second memory device at the MUX” may be performed. In some embodiments, the first memory device, the second memory device, and the buffer die are included in a memory package, such as memory package 302. At block 406 “providing from the MUX, the first data and the second data” may be performed. In some embodiments, the data may be provided to a controller, such as controller 106. In some embodiments, the data may be provided to a component included in a memory module.

In some embodiments, the method shown in flowchart 400 may further include receiving a read command, wherein the first data and the second data are received responsive to the read command. In some of these embodiments, the buffer die has a bandwidth greater than a bandwidth of the first memory device and the second memory device.

In some embodiments, the method shown in flowchart 400 may further include receiving a first read command, wherein the first data is received responsive to the first read command, and receiving a second read command, wherein the second data is received responsive to the second read command. In some of these embodiments, the MUX provides the first data prior to providing the second data.

Optionally, the method shown in flowchart 400 may further include “receiving third data from a third memory device at a second MUX of a second buffer die” as indicated by block 408, and “receiving fourth data from a fourth memory device at the second MUX” as indicated by block 410. In some embodiments, the third memory device, the fourth memory device, and the second buffer die are included in a second memory package.

The method shown in flowchart 400 may further optionally include block 412 where “providing from the second MUX, the third data and the fourth data” is performed and block 414 where “receiving, at a third MUX, the first data, the second data, the third data, and the fourth data” is performed. In some embodiments, a bandwidth of the third MUX is greater than a bandwidth of the MUX and the second MUX.

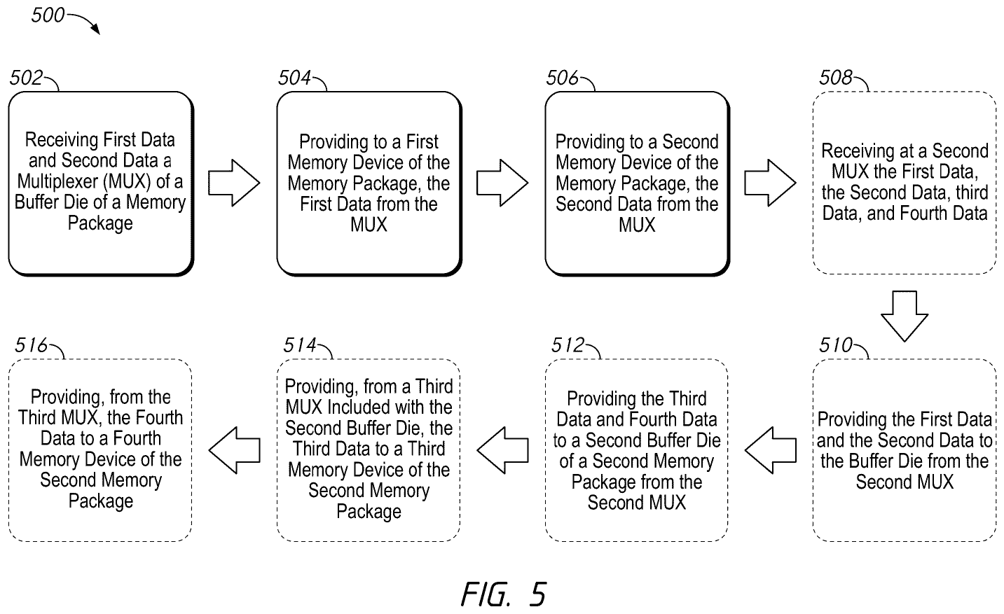

FIG. 5 is a flow chart illustrating a method according to at least one embodiment of the present disclosure. The method shown in flowchart 500 may be performed in whole or in part by any or all of the memory packages disclosed herein, such as memory package 302, in some embodiments. The method shown in flowchart 500 may be performed in whole or in part by a memory module, such as memory module 300 and/or memory module 102 in some embodiments.

At block 502, “receiving first data and second data a multiplexer (MUX) of a buffer die of a memory package” may be performed. At block 504, “providing to a first memory device of the memory package, the first data from the MUX” may be performed. At block 506, “providing to a second memory device of the memory package, the second data from the MUX” may be performed. Optionally the method shown in flowchart 500 may further include storing the first data, the second data, or a combination thereof, in a buffer of the MUX.

In some embodiments, the method shown in flowchart 500 may further include receiving a write command. The first data and the second data are received responsive to the write command. In some of these embodiments, the buffer die has a bandwidth greater than a bandwidth of the first memory device and the second memory device.

In some embodiments, the method shown in flowchart 500 may further include receiving a first write command, wherein the first data is received responsive to the first write command, and receiving a second write command, wherein the second data is received responsive to the second write command. In some of these embodiments, the MUX provides the first data prior to providing the second data.

Optionally, the method shown in flowchart 500 may further include block 508 where “receiving at a second MUX the first data, the second data, third data, and fourth data” is performed. In some embodiments, the second MUX may be included in a memory module. The method shown in flowchart 500 may further optionally include block 510 where “providing the first data and the second data to the buffer die from the second MUX” is performed, block 512 where “providing the third data and fourth data to a second buffer die of a second memory package from the second MUX” is performed, block 514 where “providing, from a third MUX included with the second buffer die, the third data to a third memory device of the second memory package” is performed, and block 516 where “providing, from the third MUX, the fourth data to a fourth memory device of the second memory package” is performed.

The systems, methods, and apparatuses disclosed herein provide for multiplexing data in memory packages that include multiple memory die and a buffer die. In some applications, this may reduce or eliminate the need for additional components on the memory modules, which may reduce compatibility issues. In some applications, the multiplexing components of the memory package may be included in addition to the multiplexing components of the memory module. This may increase the multiplexing capabilities of the memory module.

Of course, it is to be appreciated that any one of the examples, embodiments or processes described herein may be combined with one or more other examples, embodiments and/or processes or be separated and/or performed amongst separate devices or device portions in accordance with the present systems, devices and methods. For example, a buffer die may have all or some of the features of the buffer dice disclosed in the present application.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of memory devices; and
a buffer die in communication with the plurality of memory devices, the buffer die comprising a multiplexer (MUX) configured to transmit data to and receive the data from the plurality of memory devices.

2. The apparatus of claim 1, wherein the MUX comprises a buffer configured to temporarily store the data.

3. The apparatus of claim 1, wherein the plurality of memory devices and buffer die are included in a first memory package, and the apparatus further comprises a second memory package comprising a second plurality of memory devices and a second buffer die comprising a second MUX.

4. The apparatus of claim 3, further comprising a third MUX configured to transmit the data to and receive the data from the first memory package and the second memory package.

5. The apparatus of claim 4, wherein the third MUX comprises a buffer.

6. The apparatus of claim 4, wherein the first memory package, the second memory package, and the third MUX are included in a memory module.

7. The apparatus of claim 1, wherein the plurality of memory devices have a first bandwidth, and the buffer die has a second bandwidth greater than the first bandwidth.

8. The apparatus of claim 1, wherein the plurality of memory devices and buffer die are included in a memory package, wherein individual ones of the plurality of memory devices are configured to provide data as a first burst length, and the memory package is configured to provide the data a second burst length greater than the first burst length.

9. A method comprising:
receiving first data from a first memory device at a multiplexer (MUX) of a buffer die;
receiving second data from a second memory device at the MUX, wherein the first memory device, the second memory device, and the buffer die are included in a memory package; and
providing from the MUX, the first data and the second data.

10. The method of claim 9, further comprising receiving a read command, wherein the first data and the second data are received responsive to the read command.

11. The method of claim 10, wherein the buffer die has a bandwidth greater than a bandwidth of the first memory device and the second memory device.

12. The method of claim 9, further comprising:
receiving a first read command, wherein the first data is received responsive to the first read command; and
receiving a second read command, wherein the second data is received responsive to the second read command,
wherein the MUX provides the first data prior to providing the second data.

13. The method of claim 9, further comprising:
receiving third data from a third memory device at a second MUX of a second buffer die;
receiving fourth data from a fourth memory device at the second MUX, wherein the third memory device, the fourth memory device, and the second buffer die are included in a second memory package;
providing from the second MUX, the third data and the fourth data; and
receiving, at a third MUX, the first data, the second data, the third data, and the fourth data.

14. The method of claim 13, wherein a bandwidth of the third MUX is greater than a bandwidth of the MUX and the second MUX.

15. A method comprising:
receiving first data and second data a multiplexer (MUX) of a buffer die of a memory package;
providing to a first memory device of the memory package, the first data from the MUX; and
providing to a second memory device of the memory package, the second data from the MUX.

16. The method of claim 15, further comprising receiving a write command, wherein the first data and the second data are received responsive to the write command.

17. The method of claim 16, wherein the buffer die has a bandwidth greater than a bandwidth of the first memory device and the second memory device.

18. The method of claim 9, further comprising:
receiving a first write command, wherein the first data is received responsive to the first write command; and
receiving a second write command, wherein the second data is received responsive to the second write command,
wherein the MUX provides the first data prior to providing the second data.

19. The method of claim 15, further comprising storing the first data, the second data, or a combination thereof, in a buffer of the MUX.

20. The method of claim 15, further comprising:
receiving at a second MUX the first data, the second data, third data, and fourth data;
providing the first data and the second data to the buffer die from the second MUX;
providing the third data and the fourth data to a second buffer die of a second memory package from the second MUX;
providing, from a third MUX included with the second buffer die, the third data to a third memory device of the second memory package; and
providing, from the third MUX, the fourth data to a fourth memory device of the second memory package.
